(19) United States
(12) Patent Application Publication
(10) Pub. No.: US 2026/0150554 A1
(43) Pub. Date: May 28, 2026

(54) DISPLAY PANEL, MANUFACTURING METHOD THEREOF, AND DISPLAY DEVICE

(71) Applicants: MIANYANG HKC OPTOELECTRONICS TECHNOLOGY CO., LTD., Mianyang (CN); HKC CORPORATION LIMITED, Shenzhen (CN)

(72) Inventors: QIN LIANG, Shenzhen (CN); Zhisheng XIE, Shenzhen (CN); Yangling TANG, Shenzhen (CN); Xiufeng ZHOU, Shenzhen (CN); Lidan YE, Shenzhen (CN)

(21) Appl. No.: 19/177,683

(22) Filed: Apr. 14, 2025

(30) Foreign Application Priority Data
Apr. 15, 2024 (CN) 202410451937.4

(51) Int. Cl. H10K 59/80; H10K 59/12

(52) U.S. Cl. CPC H10K 59/873; H10K 59/1201

(57) ABSTRACT

A display panel, a manufacturing method thereof, and a display device are disclosed. The display panel includes a substrate, a display component layer, a sealing layer, a first sealing dam, a second sealing dam, and an encapsulation cover. The display component layer is arranged on the substrate. The sealing layer covers the display component layer. The first sealing dam surrounds the sealing layer and is arranged on the substrate. The second sealing dam surrounds the first sealing dam and is arranged on the substrate. The encapsulation cover is bonded to the sealing layer, the first sealing dam, and the second sealing dam. The thickness of the first sealing dam is less than the thickness of the second sealing dam.

### CROSS-REFERENCE TO RELATED APPLICATIONS

This application claims the priority and benefit of Chinese patent application number 2024104519374, titled “Display Panel, Manufacturing Method Thereof, and Display Device” and filed Apr. 15, 2024 with China National Intellectual Property Administration, the entire contents of which are incorporated herein by reference.

### TECHNICAL FIELD

This application relates to the field of display technology, and more particularly relates to a display panel, a manufacturing method thereof, and a display device.

### BACKGROUND

The description provided in this section is intended for the mere purpose of providing background information related to the present application but does not necessarily constitute prior art.

Organic light emitting diodes (OLEDs) have the advantages of surface light source, cold light, energy saving, fast response, flexibility, ultra-thinness, and low cost, and its mass production technology is becoming increasingly mature, so that OLED display panels are gradually becoming mainstream display panels. However, since the light-emitting devices in the OLED display panel have poor stability and are extremely sensitive to water and oxygen, which may cause the light-emitting devices to be oxidized and fail, the encapsulation technology is particularly critical. The purpose of encapsulation is mainly to prevent water vapor and air from entering the light-emitting devices. Related encapsulation methods may include surface encapsulation and thin film encapsulation. The surface encapsulation method uses UV-cured organic materials such as a sealing layer and a sealing dam, and after dispensing and pre-curing on the encapsulation cover, they are bonded to the substrate and UV-cured to form a sealed protection for the display component layer on the substrate.

However, when the amount of sealing layer material in the sealing dam deviates, for example, when the sealing layer material is too little, air holes may be formed near the sealing dam. On the contrary, when the sealing layer material is too much, the dam may be overflowed. Both of the above situations may affect the sealing performance of the display panel, leading to the problem of encapsulation failure.

### SUMMARY

One purpose of this application is to provide a display panel, a manufacturing method thereof, and a display device. Through the effects of the first sealing dam and the second sealing dam, even if a sufficient amount of sealing layer material is provided, the occurrence of pores and glue overflow can be prevented, the sealing performance of the display panel can be improved, and the quality of the display panel can be improved.

This application discloses a display panel, the display panel includes a substrate, a display component layer, a sealing layer, a first sealing dam, a second sealing dam, and an encapsulation cover. The display component layer is arranged on the substrate. The sealing layer covers the display component layer. The first sealing dam surrounds the sealing layer and is arranged on the substrate. The second sealing dam surrounds the first sealing dam and is arranged on the substrate. The encapsulation cover is bonded to the sealing layer, the first sealing dam, and the second sealing dam. The thickness of the first sealing dam is less than the thickness of the second sealing dam.

In some embodiments, the first sealing dam is bonded to the encapsulation cover. A first gap is defined between the first sealing dam and the substrate. The sealing layer includes a redundant piece, and the redundant piece is disposed in the first gap. One end of the redundant piece is bonded to the first sealing dam, and the other end of the redundant piece is bonded to the substrate.

In some embodiments, a second gap is defined between the first sealing dam and the second sealing dam.

In some embodiments, the spacing between the first sealing dam and the second sealing dam is 50 um to 500 um.

In some embodiments, the width of the first sealing dam is greater than or equal to the width of the second sealing dam. The width of the first sealing dam is between 400 um and 700 um. The width of the second sealing dam is between 200 um and 500 um.

In some embodiments, an inclined surface is disposed on one side of the first sealing dam facing towards the substrate, and the thickness of the first sealing dam gradually increases along the direction from the first sealing dam to the second sealing dam.

In some embodiments, the display component layer includes a pixel driving layer, a light-emitting element layer, a pixel defining layer, and an encapsulation layer. The pixel driving layer is arranged on the substrate. The light-emitting element layer is arranged on the pixel driving layer. The pixel defining layer is arranged on the pixel driving layer. The encapsulation layer covers the pixel defining layer and the light-emitting element layer. The sealing layer is arranged on the encapsulation layer.

In some embodiments, an abutment piece is further disposed on one side of the second sealing dam facing towards the first sealing dam. The abutment piece is used to abut against the first sealing dam. During the bonding process between the encapsulation cover and the substrate, the abutment piece provides the first sealing dam with a thrust pointing from the second sealing dam toward the first sealing dam.

This application further discloses a method for manufacturing a display panel, the method including:
forming a display component layer on a substrate;
forming a first sealing dam and a sealing layer surrounded by the first sealing dam on an encapsulation cover;
forming a second sealing dam on the substrate or the encapsulation cover;
bonding the encapsulation cover and the substrate so that the sealing layer adheres to the display component layer, where the sealing layer overflows to the first sealing dam to adhere the first sealing dam to the substrate;
where the thickness of the first sealing dam is less than the thickness of the second sealing dam.

This application further discloses a display device, including a driving circuit and the above-mentioned display panel, where the driving circuit is used to drive the display panel to display.

In this application, two layers of sealing dams are disposed, and the thickness of the inner first sealing dam is smaller than that of the outer second sealing dam. When dispensing adhesive on the encapsulation cover, a sufficient amount of sealing layer material can be provided to prevent the occurrence of problems such as pores. When a sufficient amount of sealing layer material is used to bond the encapsulation cover to the substrate, the first sealing dam has a smaller thickness, so that the sealing layer material can smoothly overflow from the first sealing dam, thereby preventing the film layer from being broken due to the squeeze of the sufficient amount of sealant. Furthermore, although some sealing layer material overflow from the first sealing dam, due to the effect of the second sealing dam, the overflowing sealing layer materials are only contained in the second sealing dam, and will not overflow to the outside of the sealing dam thus causing sealing failure and other problems. Through the first sealing dam and the second sealing dam, even with an excess of sealing layer material, the occurrence of glue overflow can be prevented, thereby improving the sealing performance of the display panel and improving the quality of the display panel.

### BRIEF DESCRIPTION OF DRAWINGS

The accompanying drawings are used to provide a further understanding of the embodiments according to this application, and constitute a part of the specification. They are used to illustrate the embodiments according to this application, and explain the principles of this application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel of a first embodiment of this application.

FIG. 2 is a schematic top view of a display panel of the first embodiment of this application.

FIG. 3 is a cross-sectional view of FIG. 2 along the sectional line AA'.

FIG. 4 is a schematic diagram of another display panel of the first embodiment of this application.

FIG. 5 is a schematic diagram of a display panel of a second embodiment of this application.

FIG. 6 is a schematic diagram of a display panel of a third embodiment of this application.

FIG. 7 is a flowchart of a method for manufacturing a display panel of this application.

FIG. 8 is a schematic diagram of a display device of this application.

In the drawings: 100, display panel; 110, substrate; 120, sealing layer; 121, redundant piece; 130, first sealing dam; 131, first gap; 132, inclined surface; 133, notch; 140, second sealing dam; 141, second gap; 142, abutment piece; 150, encapsulation cover; 160, display component layer; 161, pixel driving layer; 162, light-emitting element layer; 163, pixel defining layer; 164, encapsulation layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but this application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in this application can be understood depending on specific contexts.

This application will be described in detail below with reference to the accompanying drawings and some optional embodiments.

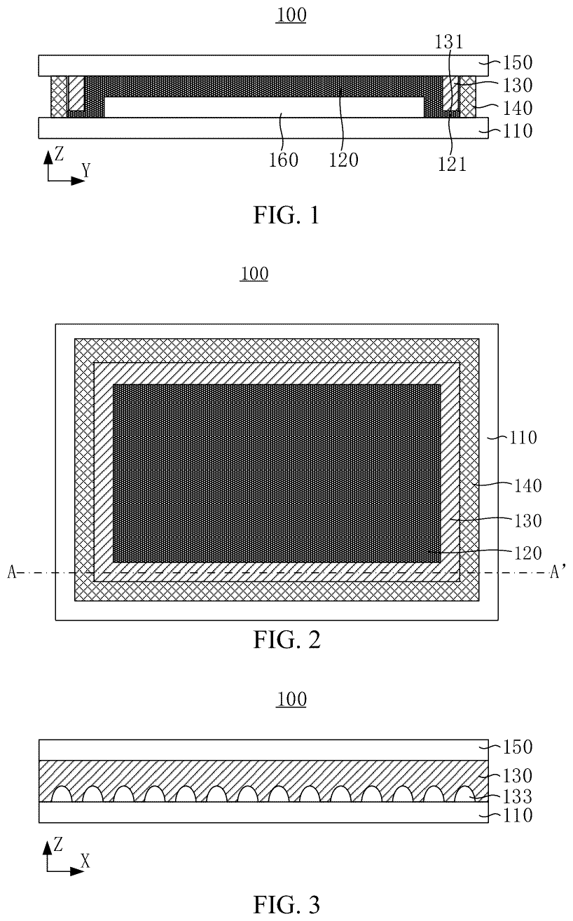

FIG. 1 is a schematic diagram of a display panel of a first embodiment of this application. As shown in FIG. 1, this application discloses a display panel 100. The display panel 100 includes a substrate 110, a display component layer 160, a sealing layer 120, a first sealing dam 130, a second sealing dam 140, and an encapsulation cover 150. The display component layer 160 is arranged on the substrate 110. The sealing layer 120 covers the display component layer 160. The first sealing dam 130 surrounds the sealing layer 120 and is arranged on the substrate 110. The second sealing dam 140 surrounds the first sealing dam 130 and is arranged on the substrate 110. The encapsulation cover 150 is bonded to the sealing layer 120, the first sealing dam 130, and the second sealing dam 140. The thickness of the first sealing dam 130 is less than the thickness of the second sealing dam 140.

In this application, two layers of sealing dams are disposed, and the thickness of the inner first sealing dam 130 is smaller than that of the outer second sealing dam 140. When dispensing adhesive on the encapsulation cover, a sufficient amount of sealing layer material can be provided to prevent the occurrence of problems such as pores. When a sufficient amount of sealing layer material is used to bond the encapsulation cover to the substrate 110, the first sealing dam 130 has a smaller thickness, so that the sealing layer material can smoothly overflow from the first sealing dam 130, thereby preventing the film layer from being broken due to the squeeze of the sufficient amount of sealant. Furthermore, although some sealing layer material overflow from the first sealing dam 130, due to the effect of the second sealing dam 140, the overflowing sealing layer materials are only contained in the second sealing dam 140, and will not overflow to the outside of the sealing dam thus causing sealing failure and other problems. Through the first sealing dam 130 and the second sealing dam 140, even with an excess of sealing layer material, the occurrence of glue overflow can be prevented, thereby improving the sealing performance of the display panel 100 and improving the quality of the display panel 100.

Continuing to refer to FIG. 1, this application proposes a sufficient amount of sealing layer material. In fact, an excess amount of sealing layer material is disposed as much as possible to prevent the occurrence of pores caused by insufficient sealing layer material. Due to the existence of the first sealing dam 130 and the thickness of the first sealing dam 130 being less than that of the second sealing dam 140, for the extra amount of the excess sealing layer material, when the substrate 110 is bonded with the encapsulation cover, there is a gap between the first sealing dam 130 and the substrate 110, so that the excess amount can smoothly overflow from the first sealing dam 130 from the gap, thereby avoiding the rupture of the film layers caused by the squeezing of excessive sealing layer material. Furthermore, through the guidance of the gap between the first sealing dam 130 and the substrate 110, the overflow of glue in an uncertain position is avoided, thereby improving the encapsulating effect of the display panel 100.

Specifically, the first sealing dam 130 is bonded to the encapsulation cover 150. A first gap 131 is defined between the first sealing dam 130 and the substrate 110. A redundant piece 121 is disposed in the sealing layer 120, and the redundant piece 121 is disposed in the first gap 131. One end of the redundant piece 121 is bonded to the first sealing dam 130, and the other end of the redundant piece 121 is bonded to the substrate 110.

In this embodiment, a first gap 131 is provided between the first sealing dam 130 and the substrate 110, so that the excess sealing layer material forms a redundant piece 121 at the position of the first gap 131. Through the bonding effect of the redundant piece 121, the first sealing dam 130 and the substrate 110 are bonded, which plays a certain sealing role and avoids the problem of random overflow of the excess sealing layer material thus resulting in poor sealing.

The extended length direction of the first sealing dam 130 arranged surrounding the sealing layer 120 is the length direction X of the first gap 131. The direction of the first sealing dam 130 pointing from the first sealing dam 130 toward the second sealing dam 140 and perpendicular to the length direction is the width direction Y. The thickness of the first gap 131 is the interval between the side of the first sealing dam 130 facing towards the substrate 110 and the substrate 110, that is, the thickness direction Z. The thickness of the first gap 131 determines the flow rate of the overflowing of the sealing layer material. When the thickness of the first gap 131 is smaller, the channel for the sealing layer material to overflow is narrower. When the thickness of the first gap 131 is larger, the channel for the sealing layer material to overflow is wider.

FIG. 2 is a schematic top view of the display panel of the first embodiment of this application. FIG. 3 is a schematic cross-sectional view of FIG. 2 along the sectional line AA'. As shown in FIGS. 2-3, the first sealing dam 130 is arranged around the display component layer 160, and the second sealing dam 140 is arranged around the first sealing dam 130. Since the first sealing dam 130 and the second sealing dam 140 are arranged in a surrounding manner, in the above solution, the thickness of the first sealing dam 130 being less than the thickness of the second sealing dam 140 may be interpreted as that the thickness of the first sealing dam 130 is less than the thickness of the second sealing dam 140 at least in some positions. For example, as shown in FIG. 3, a plurality of notches 133 are defined in the first sealing dam 130. At the positions of the plurality of notches 133, the thickness of the first sealing dam 130 is less than the thickness of the second sealing dam 140. At the non-notch positions, the thickness of the first sealing dam 130 may be less than or equal to the thickness of the second sealing dam 140.

In this solution, a plurality of notches 133 are defined in the first sealing dam 130, and an overflow channel of the redundant sealing layer material is formed at the position of each notch 133. During the process of bonding the encapsulation cover to the substrate 110, redundant pieces 121 are formed at the positions of the plurality of notches 133, and the plurality of notches 133 are filled with the redundant pieces 121 to achieve the bonding between the first sealing dam 130 and the substrate 110. Of course, the number of notches 133 is closely related to the amount of sealing layer material, and may be designed depending on actual conditions.

Specifically, along the length direction of the first sealant, the cross-sectional shape of the notch 133 may be a variety of shapes such as a semicircle, a triangle, or a polygon.

Of course, in the above embodiment, the thickness of the first sealing dam 130 being less than the thickness of the second sealing dam 140 may further include that the thickness of all the first sealing dams 130 being less than the thickness of the second sealing dam 140. In other words, the maximum thickness of the first sealing dams 130 is less than the minimum thickness of the second sealing dam 140. Since the second sealing dam 140 may require a certain degree of flatness and uniformity, the thickness of each and every position of the second sealing dam 140 is equal. That is, the minimum thickness of the second sealing dam 140 is also the average thickness of the second sealing dam 140. The first sealing dam 130 does not need to have the same thickness at each and every position, so the first sealing dam 130 may have a plurality of notches 133, but the maximum thickness of the first sealing dam 130 must be less than or equal to the average thickness of the second sealing dam 140.

It is worth mentioning that the minimum thickness of the first sealing dam 130 needs to satisfy the requirement that the sealing layer material cannot overflow from the minimum thickness of the first sealing dam 130 during the dispensing process with the encapsulation cover. During the process of bonding the encapsulation cover to the substrate 110, the sealing layer material will be squeezed due to the film layer structures disposed on the substrate 110. In the related technology, the use of an appropriate amount of sealing layer material will not overflow from the sealing dam. In this embodiment, since sufficient or excessive sealing layer material is used, redundant piece 121 may be formed. The redundant piece 121 is at least arranged in the first gap 131. When there is an excess of sealing layer material, the redundant piece 121 may extend to the side of the first sealing dam 130 facing towards the second sealing dam 140.

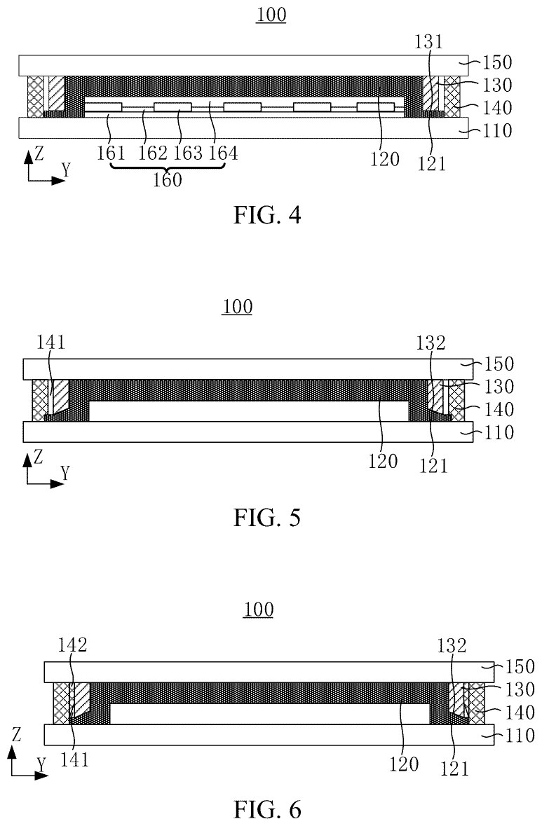

FIG. 4 is a schematic diagram of another display panel of the first embodiment of this application. As shown in FIG. 4, the display component layer 160 includes a pixel driving layer 161, a light-emitting element layer 162, a pixel defining layer 163, and an encapsulation layer 164. The pixel driving layer 161 is arranged on the substrate 110. The light-emitting element layer 162 is arranged on the pixel driving layer 161. The pixel defining layer 163 is arranged on the pixel driving layer 161. The encapsulation layer 164 covers the pixel defining layer 163 and the light-emitting element layer 162. The sealing layer 120 is arranged on the encapsulation layer 164.

In this embodiment, the encapsulation layer 164 is formed on the light-emitting element layer 162, and the sealing layer material is used on the encapsulation layer 164 for sealing, so that the thin film encapsulation technology is combined with the surface encapsulation technology to achieve a better sealing effect. The encapsulation layer 164 may include only one inorganic layer, or the encapsulation layer 164 may be a stack of two inorganic layers and an organic layer disposed between the two inorganic layers. The sealing layer 120 is covered on the encapsulation layer 164 to improve the situation where the encapsulation layer 164 may have cracks.

In this embodiment, the sealing layer material may be an organic glue with relatively high transmittance, which is formed on the encapsulation cover by dispensing and bonded to the substrate 110 after pre-curing.

FIG. 5 is a schematic diagram of a display panel of a second embodiment of this application. As shown in FIG. 5, on the basis of the above embodiment, this application further sets the thickness of the first sealing dam 130. Specifically, an inclined surface 132 is disposed on one side of the first sealing dam 130 facing towards the substrate 110, and the thickness of the first sealing dam 130 gradually increases in the direction from the first sealing dam 130 toward the second sealing dam 140.

It can be understood that the inclined surface 132 is arranged on the side of the first sealing dam 130 facing towards the substrate 110, and the inclined direction is along the width direction of the first sealing dam 130. In the width direction pointing from the first sealing dam 130 to the second sealing dam 140, the thickness of the first sealing dam 130 gradually increases.

In this embodiment, by setting the inclined surface 132, that is, setting a non-horizontal plane on the side of the first sealing dam 130 adjacent to the substrate 110, the excess sealing layer material can overflow through the inclined surface 132, and the contact surface between the first sealing dam 130 and the sealing layer material is increased after the inclined surface 132 is formed.

In further connection with FIG. 3, it is worth mentioning that the inclined surface 132 of this application may also be set at the notch 133 position or the non-notch position in the above embodiment. In combination with the above solution, a larger contact area between the redundant piece 121 and the first sealing dam 130 can be achieved, and a better sealing effect can be achieved. For example, an inclined surface 132 may be provided at the position of notch 133, and another inclined surface 132 may be provided at the positions other than notch 133. The position other than the notch 133 can accommodate a relatively small amount of sealing layer material, and the position of the notch 133 can accommodate relatively more sealing layer material. Under the guidance of the inclined surface 132, even if there is excess sealing layer material, this part of the sealing layer material will be solidified in the first gap 131 at the first time, and will not appear on the side of the second sealing dam 140.

FIG. 6 is a schematic diagram of a display panel of a third embodiment of this application. As shown in FIG. 6, based on the above embodiment, this application further defines a second gap 141 between the first sealing dam 130 and the second sealing dam 140.

In this embodiment, a second gap 141 is defined between the first sealing dam 130 and the second sealing dam 140, and the second gap 141 is used to accommodate more sealing layer materials. When sufficient and excess sealing layer material is used, the excess sealing layer material can enter the second gap 141 from the first gap 131, thereby achieving a larger accommodating space for the sealing layer material, thereby preventing the phenomenon that the excess sealing layer material squeezes the film layers and causes rupture when the excess sealing layer material is used. In other words, the second gap 141 becomes a buffer of the sealing layer material to accommodate the excess sealing layer material.

Specifically, the spacing between the first sealing dam 130 and the second sealing dam 140 is 50 μm to 500 μm, that is, the width of the second gap 141 is 50 μm to 500 μm. In this embodiment, the micron-sized second gap 141 is set, which is not a very large accommodation space relative to the sealing layer material, but it is enough to accommodate the excess sealing layer material. Relatively speaking, if the width of the second gap 141 is set larger, a larger gap will be formed between the first sealing dam 130 and the second sealing dam 140, thereby forming a cavity, especially when the sealing layer material cannot completely fill the second gap 141.

Specifically, the width of the first sealing dam 130 is greater than or equal to the width of the second sealing dam 140. In this solution, it is mainly considered that during the bonding process between the encapsulation cover and the substrate 110, the sealing layer material is squeezed and diffused outward, and the first sealing dam 130 is subjected to the outward force of the sealing layer material, that is, the push from the inside toward the second sealing dam 140. In this application, the width of the first sealing dam 130 is set wider, so that the adhesion between the first sealing dam 130 and the encapsulation cover is stronger, and the first sealing dam 130 is prevented from moving outward due to the above-mentioned push. In this process, better adhesion between the first sealing dam 130 and the encapsulation cover can be achieved by pre-curing the first sealing dam 130.

Specifically, the width of the first sealing dam 130 is between 400 um and 700 um, and the width of the second sealing dam 140 is between 200 um and 500 um.

Specifically, an abutment piece 142 is further disposed on the side of the second sealing dam 140 facing towards the first sealing dam 130. The abutment piece 142 is used to abut against the first sealing dam 130, and provide the first sealing dam 130 with a push pointing from the second sealing dam 140 toward the first sealing dam 130 during the bonding process between the encapsulation cover and the substrate 110.

In this embodiment, an abutment piece 142 is disposed on the side of the second sealing dam 140 facing towards the first sealing dam 130, and the abutment piece 142 is used to form a reaction force of the above-mentioned push to prevent the first sealing dam 130 from moving toward the second sealing dam 140.

Of course, in another embodiment, a second sealing dam 140 with a special shape may be disposed so that the second sealing dam 140 directly contacts the first sealing dam 130 on the side facing towards the encapsulation cover, but a second gap 141 may still be formed on the side of the second sealing dam 140 facing towards the substrate 110 to accommodate the excess sealing layer material.

In combination with the solution of providing a plurality of notches 133 in the first embodiment, in order to prevent the redundant sealing layer material from directly entering the second gap 141 and causing the first gap 131 to be unable to be fully filled, further improvements are made in this embodiment.

An extension part is further disposed on the basis of the abutment piece 142, and the extension part extends from the abutment piece 142 toward the substrate 110 and contacts the substrate 110. The extension part is arranged at the position corresponding to each notch 133. By arranging the extension part on the notch 133, after the sealing layer material passes through the first gap 131, the extension part prevents the sealing layer material from moving forward further. When the first gap 131 is filled sufficiently, it extends from the gap between the first gap 131 and the extension part to the second gap 141. Of course, this solution is for the case where there are fewer redundant pieces 121, that is, an appropriate amount of sealing layer material is used.

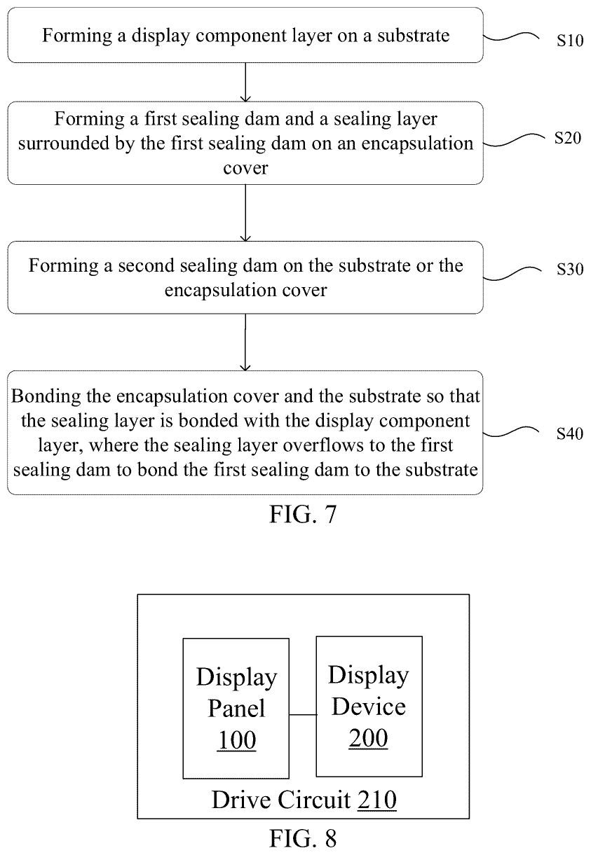

FIG. 7 is a flowchart of a method for manufacturing a display panel of this application. As shown in FIG. 7, this application discloses a method for manufacturing a display panel, the method including:
S10: forming a display component layer on a substrate;
S20: forming a first sealing dam and a sealing layer surrounded by the first sealing dam on the encapsulation cover;
S30: forming a second sealing dam on the substrate or the cover;
S40: bonding the cover and the substrate so that the sealing layer adheres to the display component layer, where the sealing layer overflows to the first sealing dam to adhere the first sealing dam to the substrate;
where the thickness of the first sealing dam 130 is less than the thickness of the second sealing dam 140.

In this application, in further connection with the previous FIGS. 1 to 6, two layers of sealing dams are disposed, and the thickness of the inner first sealing dam 130 is smaller than that of the outer second sealing dam 140. When dispensing adhesive on the encapsulation cover, a sufficient amount of sealing layer material can be provided to prevent the occurrence of problems such as pores. When a sufficient amount of sealing layer material is used to bond the encapsulation cover to the substrate 110, the first sealing dam 130 has a smaller thickness, so that the sealing layer material can smoothly overflow from the first sealing dam 130, thereby preventing the film layer from being broken due to the squeeze of the sufficient amount of sealant. Furthermore, although some sealing layer material overflow from the first sealing dam 130, due to the effect of the second sealing dam 140, the overflowing sealing layer materials are only contained in the second sealing dam 140, and will not overflow to the outside of the sealing dam thus causing sealing failure and other problems. Through the first sealing dam 130 and the second sealing dam 140, even with an excess of sealing layer material, the occurrence of glue overflow can be prevented, thereby improving the sealing performance of the display panel 100 and improving the quality of the display panel 100.

Specifically, in operation S30, the second sealing dam 140 is formed on the substrate 110. During the bonding process of the encapsulation cover and the substrate 110, when the sealing layer material overflows to the first gap 131, the sealing layer material can be prevented from leaking due to the blocking of the second sealing dam 140.

In one embodiment, the first sealing dam 130 and the second sealing dam 140 may be made of the same material, both of which may be light-absorbing materials, such as dark brown or black organic glue. By setting the dark brown or black edge sealing material, the product is more beautiful under the black state.

In another embodiment, the first sealing dam 130 and the second sealing dam 140 may be made of different materials. For example, the first sealing dam 130 may be made of an organic adhesive containing a hygroscopic material, where the hygroscopic material may be selected from calcium oxide, aluminum oxide, activated carbon, graphene, silica gel, iron oxide, etc. The second sealing dam 140 may be made of a light-absorbing material, such as a dark brown or black organic glue. By setting the hygroscopic material, it is beneficial to consume a part of the water vapor or oxygen infiltrated from the first sealing dam 130, thereby improving the service life of the product. The second sealing dam 140 may be flush with the outer edge of the product.

It is understandable that in the manufacturing process of the first sealing dam 130 and the second sealing dam 140, the material accumulation volume may be considered when calculating the amount of coating material, so that the thickness of the first sealing dam 130 is lower than the thickness of the second sealing dam 140.

FIG. 8 is a schematic diagram of a display device of this application. As shown in FIG. 8, this application discloses a display device. The display device 200 includes a driving circuit 210 and a display panel 100 in any of the above embodiments, where the driving circuit is used to drive the display panel 100 for display.

It should be noted that the inventive concept of this application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of this application with reference to some specific optional implementations, but it cannot be determined that the specific implementation of this application is limited to these implementations. For those having ordinary skill in the technical field to which this application pertains, several deductions or substitutions may be made without departing from the concept of this application, and all these deductions or substitutions should be regarded as falling in the scope of protection of this application.

What is claimed is:

1. A display panel, comprising:
a substrate;
a display component layer, arranged on the substrate;
a sealing layer, arranged to cover the display component layer;
a first sealing dam, arranged on the substrate around the sealing layer;
a second sealing dam, arranged on the substrate around the first sealing dam; and
an encapsulation cover, bonded to each of the sealing layer, the first sealing dam, and the second sealing dam;
wherein the first sealing dam has a thickness that is less than a thickness of the second sealing dam.

2. The display panel as recited in claim 1, wherein the first sealing dam is bonded to the encapsulation cover, and wherein there is defined a first gap between the first sealing dam and the substrate;
wherein the sealing layer comprises a redundant piece disposed in the first gap, wherein one end of the redundant piece is bonded to the first sealing dam, and wherein another end of the redundant piece is bonded to the substrate.

3. The display panel as recited in claim 1, wherein there is defined a second gap between the first sealing dam and the second sealing dam.

4. The display panel as recited in claim 3, wherein a spacing between the first sealing dam and the second sealing dam lies in the range of 50 um to 500 um.

5. The display panel as recited in claim 2, wherein the first sealing dam has a width that is greater than or equal to a width of the second sealing dam.

6. The display panel as recited in claim 2, wherein the first sealing dam has a width that lies in the range of 400 um and 700 um, and the second sealing dam has a width that lies in the range of 200 um and 500 um.

7. The display panel as recited in claim 2, wherein the first sealing dam comprises an inclined surface on a side facing towards the substrate, and wherein a thickness of the first sealing dam gradually increases along a direction pointing from the first sealing dam to the second sealing dam.

8. The display panel as recited in claim 2, wherein the display component layer comprises a pixel driving layer, a light-emitting element layer, a pixel defining layer, and an encapsulation layer;
wherein the pixel driving layer is arranged on the substrate, wherein the light-emitting element layer is arranged on the pixel driving layer, wherein the pixel defining layer is arranged on the pixel driving layer, wherein the encapsulation layer is arranged to cover the pixel defining layer and the light-emitting element layer, wherein the sealing layer is arranged on the encapsulation layer.

9. The display panel as recited in claim 2, wherein there is further disposed an abutment piece on a side of the second sealing dam facing towards the first sealing dam; wherein the abutment piece is used to abut against the first sealing dam, and provide the first sealing dam with a thrust that points from the second sealing dam toward the first sealing dam during a bonding process between the encapsulation cover and the substrate.

10. The display panel as recited in claim 1, wherein the first sealing dam comprises a plurality of notches, and wherein at a position of each of the plurality of notches, the first sealing dam has a thickness that is less than a thickness of the second sealing dam;
wherein at each non-notch position, the first sealing dam has a thickness that is less than or equal to the thickness of the second sealing dam.

11. The display panel as recited in claim 10, wherein each of the plurality of notches has a cross-sectional shape that is semicircular, triangular, or polygonal.

12. The display panel as recited in claim 10, wherein the first sealing dam comprises an inclined surface on a side facing towards the substrate, and wherein a thickness of the first sealing dam gradually increases along a direction pointing from the first sealing dam to the second sealing dam;
wherein the inclined surface is further disposed at the position of each of the plurality of notches.

13. A method for manufacturing a display panel, comprising:
forming a display component layer on a substrate;
forming a first sealing dam and a sealing layer surrounded by the first sealing dam on an encapsulation cover;
forming a second sealing dam on the substrate or the encapsulation cover;
bonding the encapsulation cover and the substrate so that the sealing layer is bonded with the display component layer, where the sealing layer overflows to the first sealing dam to bond the first sealing dam to the substrate;
wherein the first sealing dam has a thickness that is less than a thickness of the second sealing dam.

14. The method as recited in claim 13, wherein the first sealing dam is made of a material identical with that of the second sealing dam, wherein both the first sealing dam and the second sealing dam are each made of a light-absorbing material.

15. The method as recited in claim 13, wherein the first sealing dam and the second sealing dam are made of different materials, wherein the first sealing dam is made of an organic adhesive containing a hygroscopic material, the hygroscopic material comprising one or more selected from the group consisting of calcium oxide, aluminum oxide, activated carbon, graphene, silica gel, iron oxide;
wherein the second sealing dam is made of a light-absorbing material, the light-absorbing material comprising a dark brown or black organic adhesive.

16. A display device, comprising a display panel and a driving circuit configured to drive the display panel to display; wherein the display panel comprises a substrate, a display component layer, a sealing layer, a first sealing dam, a second sealing dam, and an encapsulation cover; wherein the display component layer is arranged on the substrate; wherein the sealing layer is arranged to cover the display component layer; wherein the first sealing dam is arranged on the substrate and surrounds the sealing layer; wherein the second sealing dam is arranged on the substrate and surrounds the first sealing dam; wherein the encapsulation cover is bonded to each of the sealing layer, the first sealing dam, and the second sealing dam; wherein the first sealing dam has a thickness that is less than a thickness of the second sealing dam.
